(19) United States
(12) Patent Application Publication
(10) Pub. No.: US 2013/0119976 A1
(43) Pub. Date: May 16, 2013

(54) High voltage detection in power system electrical high voltage line

(71) Applicant: Vasu Mogaveera, Hyderabad (IN)

(72) Inventor: Vasu Mogaveera, Hyderabad (IN)

(21) Appl. No.: 13/296,549

(22) Filed: Nov. 15, 2011

(51) Int. Cl. G01R 1/06

(52) U.S. Cl. 324/149

(57) ABSTRACT

An electrical power line voltage measurement device comprises a probe including an insulated shield supporting an electrode to sense voltage from one phase of the power line. The shield houses a high voltage resistor connected in series with the electrode. A meter comprises a housing operatively associated with the shield and enclosing a measurement circuit electrically connected to the high voltage resistor for measuring leakage current. A calibration circuit correlates measured leakage current to approximate power line voltage. A display is driven by the measurement circuit for displaying approximate power line voltage.

### CROSS-REFERENCE TO RELATED APPLICATIONS

Not Applicable.

### FEDERALLY SPONSORED RESEARCH OR DEVELOPMENT

Not Applicable.

### MICROFICHE/COPYRIGHT REFERENCE

Not Applicable.

### FIELD

This disclosure relates to a high voltage meter for use with electrical power lines and, more particularly, to a direct high voltage measurement device.

### BACKGROUND

Electrical power distribution systems often include overhead electrical power distribution lines mounted upon poles by a wide variety of mounting structure. Other distribution systems include underground distribution lines in which protected cables run under the ground surface. It is often necessary to take voltage measurements of distribution and transmission lines while testing for induced or live power line or equipment.

Known high voltage safety line detectors, meters and testers comprise high resistance probes connected in series with a calibrated panel meter to read the voltage. They are designed for use as safety tools by high voltage line maintenance workers to verify the status of the line or equipment as nominal, induced or de-energized. Known devices for providing such measurements include contact type and non-contact type.

The direct high voltage measurement by contacting the live high voltage power lines by using high voltage measuring and detecting equipment is often cumbersome due to distance of the power line from the ground. There are also safety concerns since voltage levels are generally more than 69 kV in an electrical power system. A non-contact type measurement technique does not require that the testing equipment directly contact the power line. However, the conventional non-contact voltage testing devices determine only the presence of a voltage on the line. They do not show the magnitude of the voltage. The approximate magnitude of the voltage is necessary to understand the voltage levels in the electrical power system. Also, decisions must often be made with respect to voltage presence due to induced voltage or voltage due to overloading or voltage levels of different electrical lines. There can also be voltage accuracy issues with floating high voltages.

The disclosure is directed to improvements in high voltage measurement devices.

### SUMMARY

As disclosed herein, a measurement device displays power line voltage level from one phase of the power line.

Broadly, there is disclosed herein an electrical power line voltage measurement device comprising a probe including an insulated shield supporting an electrode to sense voltage from one phase of the power line. The shield houses a high voltage resistor connected in series with the electrode. A meter comprises a housing operatively associated with the shield and enclosing a measurement circuit electrically connected to the high voltage resistor for measuring leakage current. A calibration circuit correlates measured leakage current to approximate power line voltage. A display is driven by the measurement circuit for displaying approximate power line voltage.

It is a feature that a handle portion is integrally formed with the housing. A hot stick may be selectively attached to the housing.

The measurement circuit may comprise a micro-ammeter circuit.

It is a feature that the calibration circuit comprises a resistor having a value correlated to a particular line voltage range.

It is another feature that the calibration circuit comprises a variable resistor having a value selectively correlated to a particular line voltage at a pre-select distance or a preselect line voltage range.

The variable resistor may have a value selectively correlated to one of a plurality of power line voltage ranges.

It is another feature to provide a digital display device.

There is also disclosed herein a portable electrical power line voltage measurement device comprising a probe including an elongate insulated shield connected to a handle portion at a near end and an electrode at an opposite distal end to sense voltage from one phase of the power line. A meter housing is operatively associated with the probe. An electrical circuit comprises a high voltage resistor connected in series with the electrode. A measurement circuit connected to the high voltage resistor measures leakage current. A calibration circuit correlates measured leakage current to approximate power line voltage and a display in the meter housing is driven by the measurement circuit for displaying approximate power line voltage.

Other features and advantages will be apparent from a review of the entire specification, including the appended claims and drawings.

### BRIEF DESCRIPTION OF THE DRAWINGS

FIG. 1 is a perspective view of use of a high voltage measurement device as disclosed herein;

FIG. 2 is a side perspective view of the measurement device; and

FIG. 3 is an electrical schematic of the measurement device.

### DETAILED DESCRIPTION

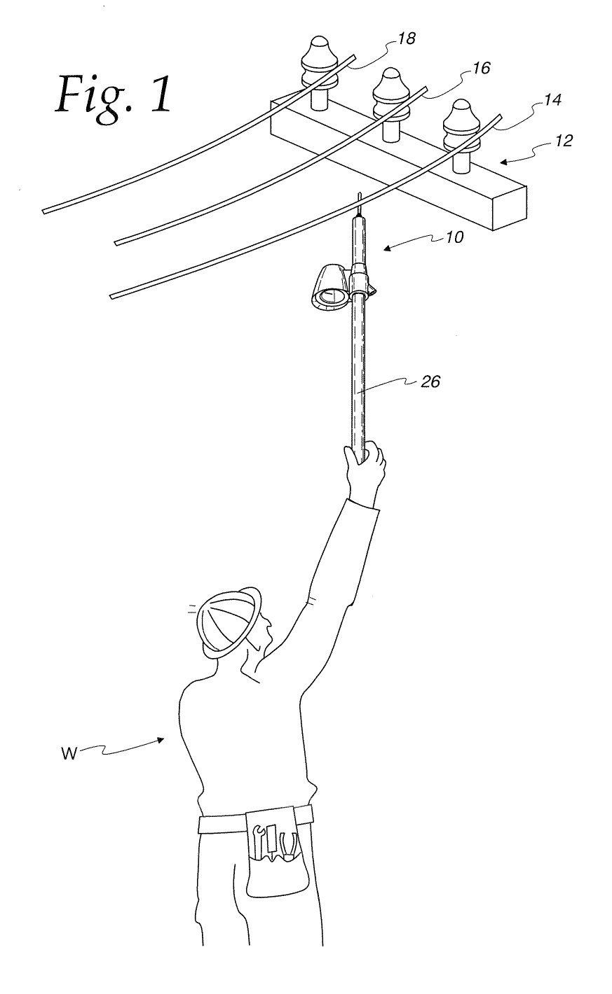

Referring initially to FIG. 1, a portable high voltage measurement device 10 is shown for measuring approximate voltage for a single phase in a high voltage distribution and transmission line system 12. The distribution and transmission line system 12 includes three lines in the form of conductors 14, 16 and 18 carrying high voltage power of alternating current with each line being 120° out of phase with the other lines, as is conventional. The measurement device 10 may be used by a maintenance worker W for measuring voltage such on the electrical conductor 14 as illustrated in FIG. 1. The measurement device 10 may also be used to measure other voltages, such underground high voltage lines directly or using cable capacitive test points if present.

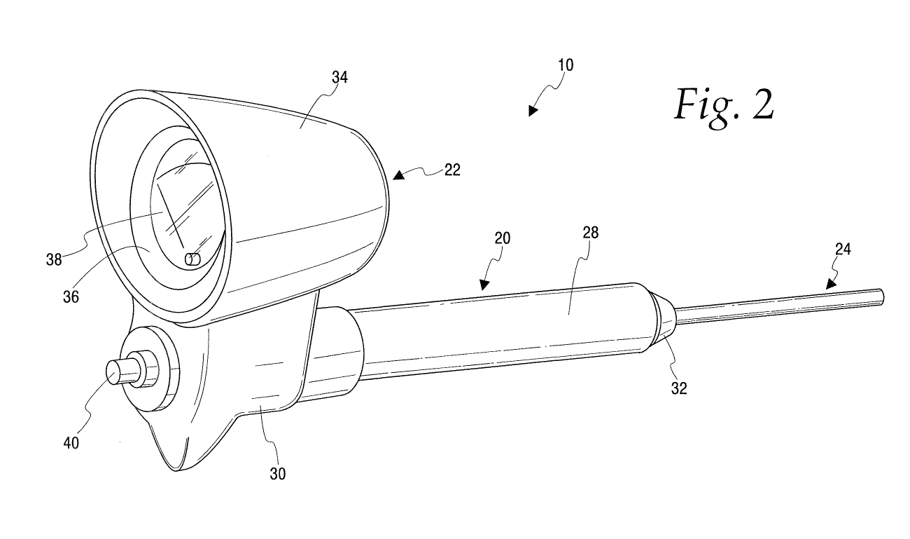

Referring also to FIG. 2, the measurement device 10 comprises a probe 20, a meter 22, an electrode 24 and a hot stick 26, see FIG. 1. The hot stick 26 is for extending length of the measurement device 10, as is conventional, to reach the line being tested.

The probe 20 comprises an elongate cylindrical insulated shield 28 connected to a handle portion 30 at a near end and a terminal 32 at a distal end. The terminal 32 threadably receives the electrode 24. The electrode 24 can be a straight probe as shown, or a hook or clamp, or the like, as necessary or desired. The meter 22 comprises a housing 34 integrally formed with the handle portion 30. The housing 34 is frustoconical in shape including a bottom bezel 36 through which a display 38 is visible. The display 38 can be an analog display or a digital display. An adaptor 40 on the handle portion 30 is aligned with the shield 28 and is adapted to secure the hot stick 26 in a conventional manner.

In use, the measurement device 10 is held proximate the power line 14. The measurement device 10 is extended, by gripping the hot stick 26, to place the electrode 24 in contact with the power line 14. An approximation of actual power line voltage will be displayed on the display 38.

The measurement device 10 will be used by maintenance personnel for detecting high voltage in the overhead or underground high voltage lines of the electrical power system. The voltage can be as low as 100V at capacitive test points of the URD high voltage cable and up to 69 kV for overhead lines. The measurement device 10 is capable of measuring any of these voltages. Utilizing the measurement device 10 only one phase of the line is used for the voltage measurement. As such, the measurement device 10 detects the voltage without a closed circuit.

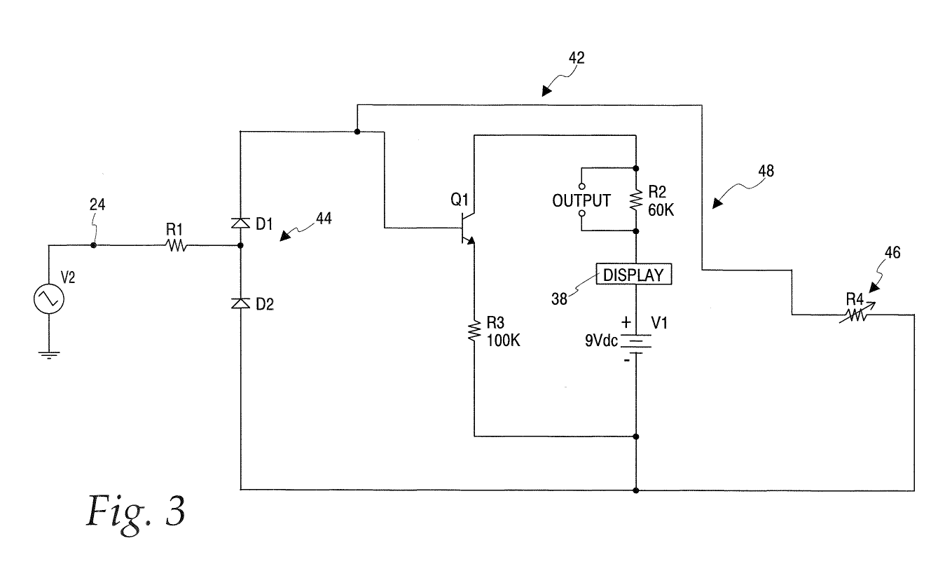

Referring to FIG. 3, an electrical circuit 42 is shown for the measurement device 10. The electrical circuit 42 uses the micro-ammeter method for measuring approximate line voltage. As will be apparent, other techniques for measuring voltage could also be used.

The circuit 42 includes a high voltage resistor R1. The high voltage resistor R1 is located in the probe 20, particularly within the shield 28, and is electrically connected in series with the electrode 24. The voltage V2 represents applied voltage that will be measured by the circuit 42. The electrical circuit will display approximate line voltage responsive thereto.

The electrical circuit 42 includes a rectifier circuit 44 comprising series connected diodes D1 and D2 having their junction connected to the high voltage resistor R1. This circuit works as a voltage to current converter. The diode D1 is connected to the base of a transistor Q1. The opposite side of the diode D2 is connected via a resistor R3 to an emitter of the transistor Q1. This circuit comprises a transistor amplifier circuit. The transistor Q1 is biased by leakage current flowing through the base of the transistor Q1 based on the applied voltage represented by V2. The corresponding current which is flowing in the collector of the transistor Q1 is equivalent actual high voltage being applied to the circuit 42. The collector current is controlled through a calibration circuit 46 comprising an external resistance in the form of a potentiometer R4 connected across the transistor amplifier circuit as shown in FIG. 3. The electrical circuit 42 is powered by a battery V1. The battery V1 powers a measurement circuit 48 for measuring transistor collector current. The measurement circuit 48 comprises a resistor R2 connected to the collector and which is connected in series with the display 34 and the battery V1.

The electrical circuit 42 is adapted to measure the applied voltage at the electrode 24. In one embodiment the collector current through the resistor R2 drives the display 38. Alternatively, the output voltage across the resistor R2 can be sent to an analog to digital converter and fed to a microcontroller to display the high voltage in digital form.

The output voltage across the resistor R2 varies from 50 mV at an applied 100V, such as a capacitive test point, to 2.4V at an applied 69 kV, for 69 kV RMS high voltage line. The resistance of the potentiometer R4 is adjusted to obtain the output voltage for the applied voltage from 100V to 69 kV. The value of the potentiometer is selected according to the desired voltage range. For example, a 50 k ohm potentiometer is used for voltages between 25 kV and 69 kV. The 500 k ohm potentiometer is used for voltages between 5 kV to 25 kV and a 7000 k ohm potentiometer is used for voltages less than 5 kV.

As described, applied voltage from the single phase power line develops leakage current which biases the transistor Q1. The corresponding current which is flowing in the collector of the transistor Q1 corresponds to the high voltage being applied to the circuit 42 and is represented by the output voltage across the resistor R2 or shown on the display 38. Thus, the measurement device 10 provides an approximation of the high voltage measurement on the high voltage line being detected. This results in a simple voltage detection circuit for voltage measurement and allows voltages from 100V to 69 kV to be measured.

Thus, by using the measurement device 10, a voltage detection method is possible that gives approximate voltage magnitude with a tolerance of plus or minus 20% with a high voltage power line, or the like. The measurement circuit is calibrated for the various voltage levels. This provides for simple voltage detection at any rating of voltage line.

It will be appreciated by those skilled in the art that there are many possible modifications to be made to the specific forms of the features and components of the disclosed embodiments while keeping within the spirit of the concepts disclosed herein. Accordingly, no limitations to the specific forms of the embodiments disclosed herein should be read into the claims unless expressly recited in the claims. Although a few embodiments have been described in detail above, other modifications are possible. Other embodiments may be within the scope of the following claims.

1. An electrical power line voltage measurement device comprising:
a probe including an insulated shield supporting an electrode to sense voltage from one phase of the power line, the shield housing a high voltage resistor connected in series with the electrode; and
a meter comprising a housing operatively associated with the shield and enclosing a measurement circuit electrically connected to the high voltage resistor for measuring leakage current, a calibration circuit for correlating measured leakage current to approximate power line voltage and a display driven by the measurement circuit for displaying approximate power line voltage.

2. The electrical power line voltage measurement device of claim 1 further comprising a handle portion integrally formed with the housing.

3. The electrical power line voltage measurement device of claim 1 further comprising a hot stick selectively attached to the housing.

4. The electrical power line voltage measurement device of claim 1 wherein the measurement circuit comprises a micro-ammeter circuit.

5. The electrical power line voltage measurement device of claim 1 wherein the calibration circuit comprises a resistor having a value correlated to a particular line voltage range.

6. The electrical power line voltage measurement device of claim 1 wherein the calibration circuit comprises a variable resistor having a value selectively correlated to a particular line voltage range.

7. The electrical power line voltage measurement device of claim 1 wherein the calibration circuit comprises a variable resistor having a value selectively correlated to a preselect line voltage range.

8. The electrical power line voltage measurement device of claim 1 wherein the calibration circuit comprises a variable resistor having a value selectively correlated to one of a plurality of power line voltage ranges.

9. The electrical power line voltage measurement device of claim 1 wherein the device is adapted to measure line voltages from about 100V to about 69 kV.

10. The electrical power line voltage measurement device of claim 1 wherein the display comprises a digital voltage display.

11. A portable electrical power line voltage measurement device comprising:
a probe including an elongate insulated shield connected to a handle portion at a near end and an electrode at an opposite distal end to sense voltage from one phase of the power line;
a meter housing operatively associated with the probe; and
an electrical circuit comprising a high voltage resistor connected in series with the electrode, a measurement circuit connected to the high voltage resistor for measuring leakage current, a calibration circuit for correlating measured leakage current to approximate power line voltage and a display in the meter housing driven by the measurement circuit for displaying approximate power line voltage.

12. The portable electrical power line voltage measurement device of claim 11 wherein the handle portion is integrally formed with the housing.

13. The portable electrical power line voltage measurement device of claim 11 further comprising a hot stick selectively attached to the housing.

14. The portable electrical power line voltage measurement device of claim 11 wherein the measurement circuit comprises a micro-ammeter circuit.

15. The portable electrical power line voltage measurement device of claim 11 wherein the calibration circuit comprises a resistor having a value correlated to a particular line voltage range.

16. The portable electrical power line voltage measurement device of claim 11 wherein the calibration circuit comprises a variable resistor having a value selectively correlated to a particular line voltage range.

17. The portable electrical power line voltage measurement device of claim 11 wherein the calibration circuit comprises a variable resistor having a value selectively correlated to a preselect line voltage range.

18. The portable electrical power line voltage measurement device of claim 11 wherein the calibration circuit comprises a variable resistor having a value selectively correlated to one of a plurality of power line voltage ranges.

19. The portable electrical power line voltage measurement device of claim 11 wherein the device is adapted to measure line voltages from about 100V to about 69 kV.

20. The portable electrical power line voltage measurement device of claim 11 wherein the display comprises a digital voltage display.
